(19) United States
(12) Patent Application Publication
(10) Pub. No.: US 2009/0111252 A1
(43) Pub. Date: Apr. 30, 2009

(54) METHOD FOR FORMING DEEP WELL REGION OF HIGH VOLTAGE DEVICE

(75) Inventors: Chih-Jen Huang, Hsinchu (TW); Ching-Ming Lee, Miaoli County (TW); Wei-Lun Hsu, Hsinchu County (TW); Chao-Yuan Su, Hsinchu City (TW); Chun-Hsiung Peng, Taoyuan County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/928,133

(22) Filed: Oct. 30, 2007

(51) Int. Cl. H01L 21/265

(52) U.S. Cl. 438/530; 257/E21.346

(57) ABSTRACT

A method of fabricating a deep well region of a high voltage device is provided. The method includes designating a deep well region that includes a designated highly doped region and a designed scarcely doped region in a substrate. A mask layer, which covers a periphery of the designated deep well region, is formed over the substrate, wherein the mask layer includes a plurality of shielding parts to cover a portion of the designated scarcely doped region. Using the mask layer as an implantation mask, an ion implantation process is performed to implant dopants into the substrate exposed by the mask and to form a plurality of undoped regions in the designated scarcely doped region covered by the shielding parts. The dopants in the designated scarcely doped region are then induced to diffuse to the undoped regions.

### BACKGROUND OF THE INVENTION

1. Field of Invention

The present invention relates to a method for fabricating a high voltage metal oxide semiconductor device. More particularly, the present invention relates to a method of forming deep well region having different dopant concentrations by using a single implantation process.

2. Description of Related Art

High voltage metal oxide semiconductor (MOS) device is a widely used semiconductor device. Typically, it is essential for a high voltage metal oxide semiconductor device to have a very high breakdown voltage (Vbd) and a low on-resistance (Ron) during operation. A high breakdown voltage raises the stability of the device, while a low on-resistance influences its operating characteristic for achieving a higher drain saturation current during the operation of the device.

However, as this type of device reaches the maximum breakdown voltage, a higher on-resistance is resulted, and the drain saturation current becomes smaller. To lower the on-resistance of a device, it is necessary to increase the dopant concentration in the drift region between the drain and the channel. However, increasing the dopant concentration in the drift region would prevent the drift region from completely depleted. A decrease in the breakdown voltage is thereby resulted. In order to resolve these problems, a double reduced surface field structure is provided. This type of structure adopts an extended drain region (N type deep well region) to raise the breakdown voltage. Further, there is an increase of charges in the drain region via a top layer (P type top layer) under the isolation structure in the deep well region in this type of structure to increase the breakdown voltage. Moreover, during the high-voltage operation of the device, the top layer facilitates the depletion of the extended drain region to provide the device with a high breakdown voltage. Hence, in order for the extended drain region to deplete during the high voltage operation, the dopant concentrations of the top layer and the extended drain region must be appropriately controlled to achieve a high breakdown voltage of the device.

Currently, the structure of a high-current, high-voltage device that has been applied in the industry shows an extended oval shape, which includes two semicircular sections and a rectangular section. However, the device characteristics of the rectangular section and the semicircular sections of this type of high-current, high-voltage device are significantly different. For the rectangular section, increasing the dopant concentration in the P-top layer or decreasing the dopant concentration in the extended drain region can increase the breakdown voltage. However, such dopant distributions would lower the breakdown voltage in the semicircular sections. Therefore, in order for the device to have a higher breakdown voltage, the fabrication process must be able to provide, according to the different structures, different dopant concentrations for the different extended drain regions or for the different P-top layers. In a typical process, two photomasks must employ to perform two ion implantation processes for the different regions. This approach not only increases the operational cost significantly, the productivity is affected.

### SUMMARY OF THE INVENTION

The present invention is to provide a method for fabricating a deep well region, wherein a single ion implantation process is capable of forming a region having two dopant concentrations.

The present invention is to provide a method for fabricating a deep well region, wherein a single photomask is used to form a region having two dopant concentrations.

The present invention is to provide a method for fabricating a deep well region, wherein the current process flow remains unchanged and a region having two dopant concentrations is formed.

The present invention is to provide a method for fabricating a deep well region, wherein the productivity is unaffected while a region having two dopant concentrations is formed.

The present invention is to provide a method for fabricating a deep well region of a high voltage device. The method includes providing a substrate, and the substrate includes a designated deep well region, wherein the designated deep well region includes a designated highly doped region and a designated scarcely doped region. Thereafter, a mask layer is formed on the substrate, wherein the mask layer covers the periphery of the designated deep well region and the mask layer has a plurality of shielding parts to cover a part of the designed scarcely doped region. Then, using the mask layer as an implantation mask, an ion implantation process is performed to implant dopants in the designated deep well region, wherein the plurality of undoped regions is formed in the designated scarcely doped region covered by the shielding parts. Thereafter, the dopants in the designated scarcely doped region diffuse to the undoped region to form a scarcely doped region in the designated scarcely doped region and a highly doped region in the designated highly doped region.

According to an embodiment of the present invention, in the deep well region of the high voltage device formed according to the above method of the invention, the designated scarcely doped region shows a rectangular shape and the designated highly doped region includes two semicircular regions configured at two ends of the rectangular-shaped designated scarcely doped region.

According to an embodiment of the present invention, the shielding parts cover the border of the rectangular-shaped designated scarcely doped region.

According to an embodiment of the present invention, the shielding parts uniformly distribute along the border of the designated scarcely doped region.

According to an embodiment of the present invention, the length of the border of the designated scarcely doped region covered by the shielding parts is about 1/12 to ⅛ of the total length of the border of the designated scarcely doped region.

According to the above method in forming the deep well region of a high voltage device of an embodiment of the present invention, a thermal cycle is performed for the dopants in the designated scarcely doped region to diffuse to the undoped region.

According to the above method in forming the deep well region of a high voltage device of an embodiment of the present invention, the thermal cycle includes a thermal annealing process.

According to the above method in forming the deep well region of a high voltage device of an embodiment of the present invention, the dosages of the dopants implanted in the designated highly doped region and the designated scarcely doped region are the same.

The present invention provides a fabrication method of a deep well region of a high voltage device. This method includes forming a mask layer on a substrate, wherein the mask layer has an opening, and the profile of the opening includes a pattern having two first sides that are substantially parallel and a plurality of concavities along the two first sides, and two connecting sections. Each connecting section includes at least an arc. Further, two ends of each connecting section are respectively connected to one end of each of the first sides. Thereafter, using the mask layer as an implantation mask, an ion implantation process is performed to implant dopants in the substrate exposed by the opening. A plurality of undoped regions that correspond to the first concavities of the opening, are formed in the substrate. Thereafter, a thermal cycle is performed to drive the dopants in the substrate to the undoped region to form a deep well region.

According to the above method in forming the deep well region of a high voltage device of an embodiment of the present invention, the shapes of the two connecting sections are substantially the same.

According to the above method in forming the deep well region of a high voltage device of an embodiment of the present invention, each connecting section shows an arc shape.

According to the above method in forming the deep well region of a high voltage device of an embodiment of the present invention, each connecting section shows a semicircular shape and the opening shows an oval-like shape.

According to the above method in forming the deep well region of a high voltage device of an embodiment of the present invention, the shapes and the dimensions of the two connecting sections are substantially different.

According to the above method in forming the deep well region of a high voltage device of an embodiment of the present invention, wherein one of the two connecting sections includes one big arc, while another one of the two connecting sections includes a plurality of first small arcs and a plurality of second small arcs, and the first small arcs and the second small arcs are arranged alternately in two rows. The alternately arranged first small arcs and second small arcs are connected by one of the second sides having a plurality of second concavities there-along to form an opening that shows a palm-like shape.

According to the above method in forming the deep well region of a high voltage device of an embodiment of the present invention, the length of each of the second concavities is about 1/12 to ⅛ of the distance between the two ends of each of the second sides.

According to the above method in forming the deep well region of a high voltage device of an embodiment of the present invention, the second concavities show a rectangular shape, a U shape or an arc shape.

According to the above method in forming the deep well region of a high voltage device of an embodiment of the present invention, each second side shows a saw-teeth shape.

According to the above method in forming the deep well region of a high voltage device of an embodiment of the present invention, the first concavities are uniformly distributed along the first side of the opening.

According to the above method in forming the deep well region of a high voltage device of an embodiment of the present invention, the length of each of the first concavities is about 1/12 to ⅛ of the distance between the two ends of each of the first sides.

According to the above method in forming the deep well region of a high voltage device of an embodiment of the present invention, each of the first concavities shows a rectangular shape, a U-shape or an arc shape.

According to the above method in forming the deep well region of a high voltage device of an embodiment of the present invention, each of the first side shows a saw-teeth shape.

According to the above method in forming the deep well region of a high voltage device of an embodiment of the present invention, the mask layer comprises a photoresist layer.

According to the above method in forming the deep well region of a high voltage device of an embodiment of the present invention, the thermal cycle comprises a thermal annealing process.

According to the above method in forming the deep well region of a high voltage device of an embodiment of the present invention, in the ion implantation process, dopants of the same concentration are implanted into the designated highly doped region and the scarcely doped region, respectively.

According to the above method in forming the deep well region of a high voltage device of an embodiment of the present invention, wherein an implantation process using a single mask is used to form a region with two different dopant concentrations.

According to the above method in forming the deep well region of a high voltage device of an embodiment of the present invention, wherein a single photomask is used to form a region with two different dopant concentrations.

According to the above method in forming the deep well region of a high voltage device of an embodiment of the present invention, wherein the current fabrication process remains unchanged while a region having two different dopant concentrations is formed.

According to the above method in forming the deep well region of a high voltage device of an embodiment of the present invention, wherein productivity remains unaffected, while a region having two different dopant concentrations is formed.

In order to make the aforementioned and other objects, features and advantages of the present invention comprehensible, a preferred embodiment accompanied with figures is described in detail below.

### BRIEF DESCRIPTION OF THE DRAWINGS

FIGS. 1A to 1E are schematic, top views showing selected process steps of a method for fabricating a high-current, high-voltage metal oxide semiconductor (MOS) device according to an embodiment of the present invention.

FIGS. 2A to 2E are cross-section views, along the cutting line II-II in FIGS. 1A to 1E, showing the selected process steps of a method for fabricating a high-current, high-voltage metal oxide semiconductor (MOS) device according to an embodiment of the present invention.

FIGS. 3A to 3E are schematic, top views showing selected process steps of a method for fabricating a high-current, high-voltage metal oxide semiconductor (MOS) device according to another embodiment of the present invention.

### DESCRIPTION OF EMBODIMENTS

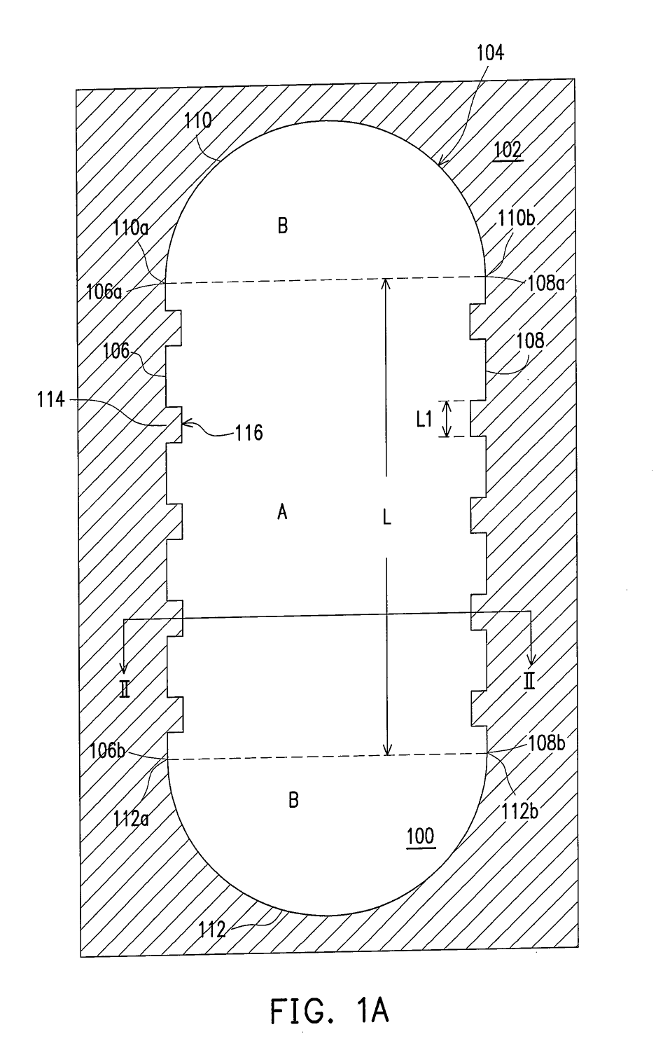

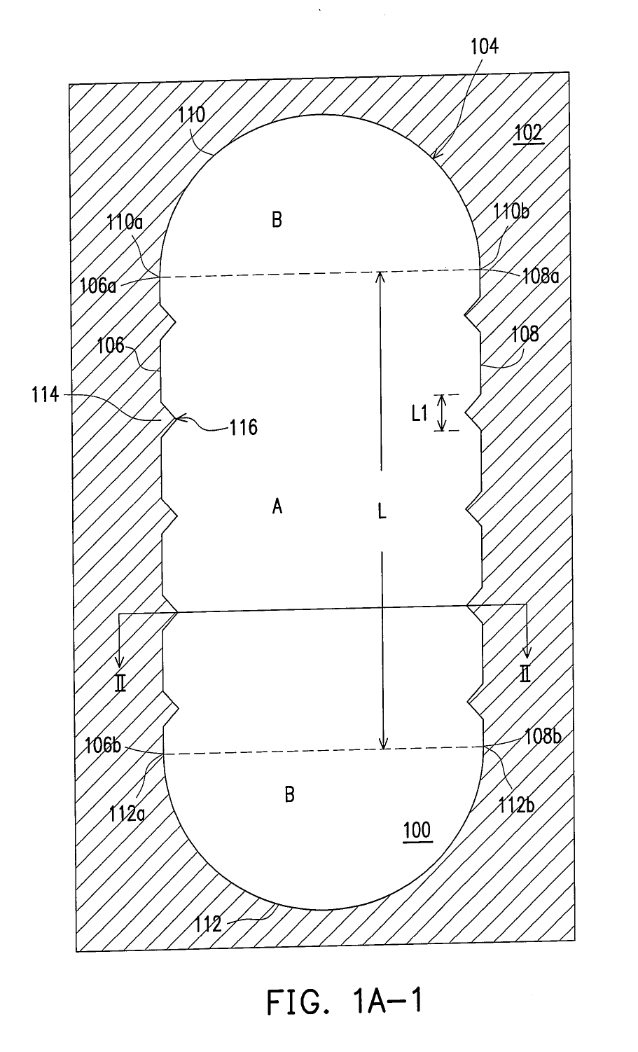

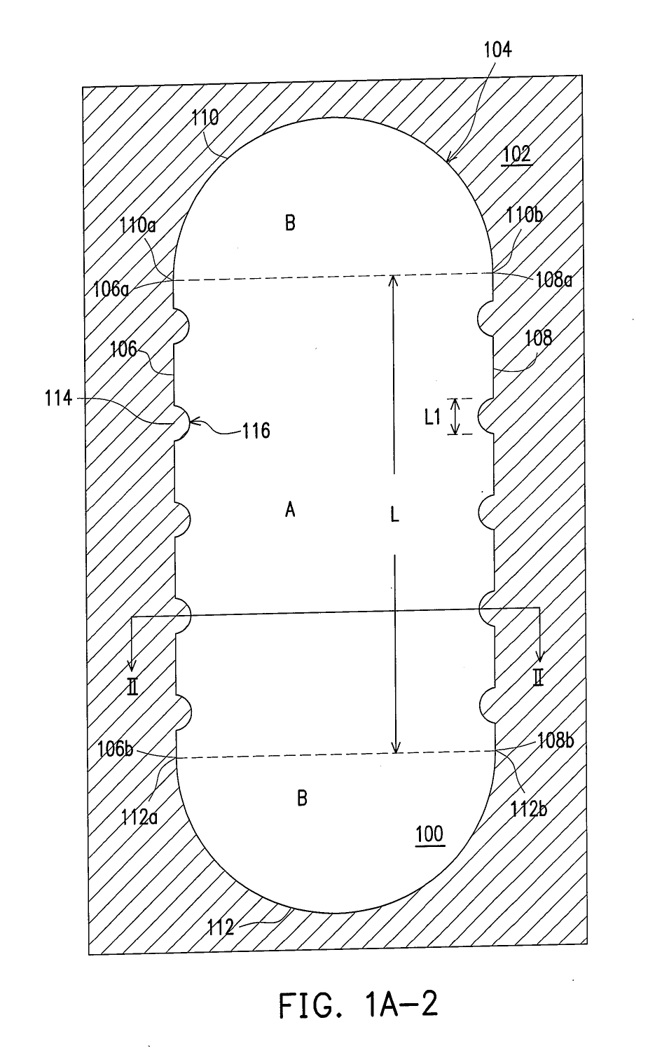

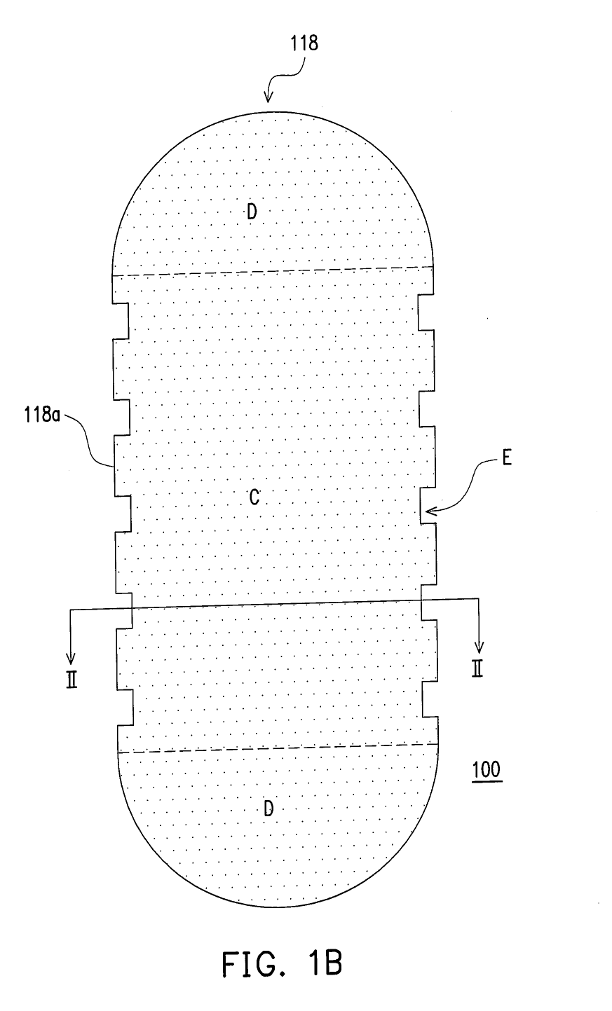

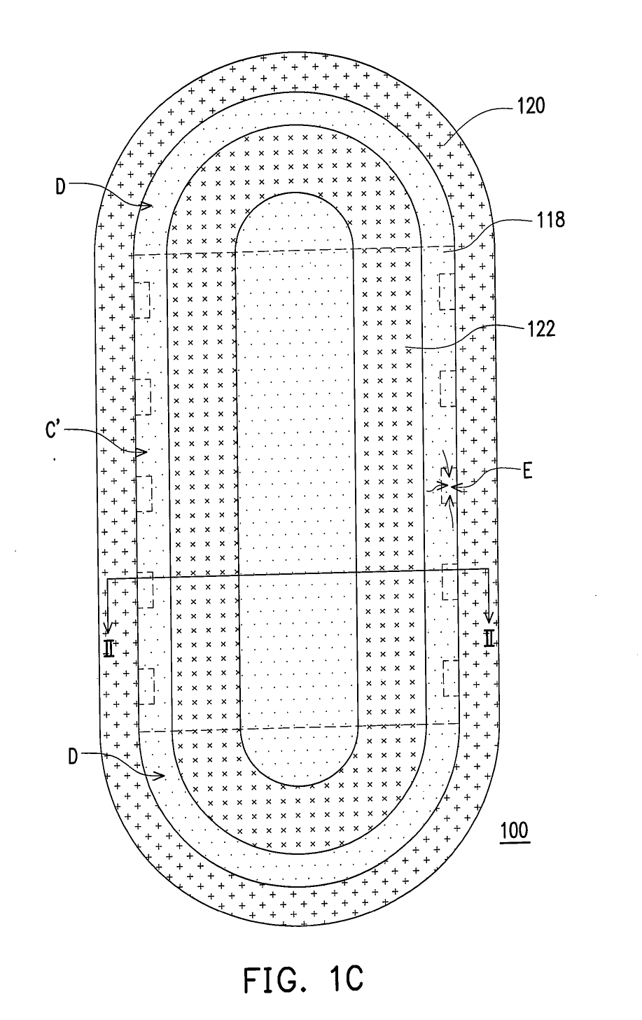

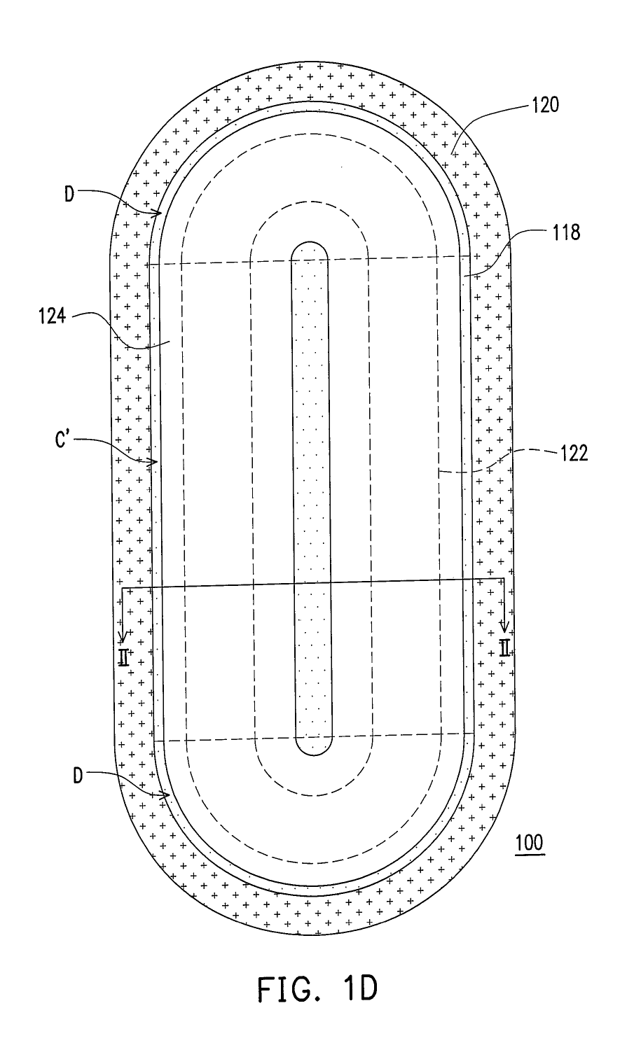

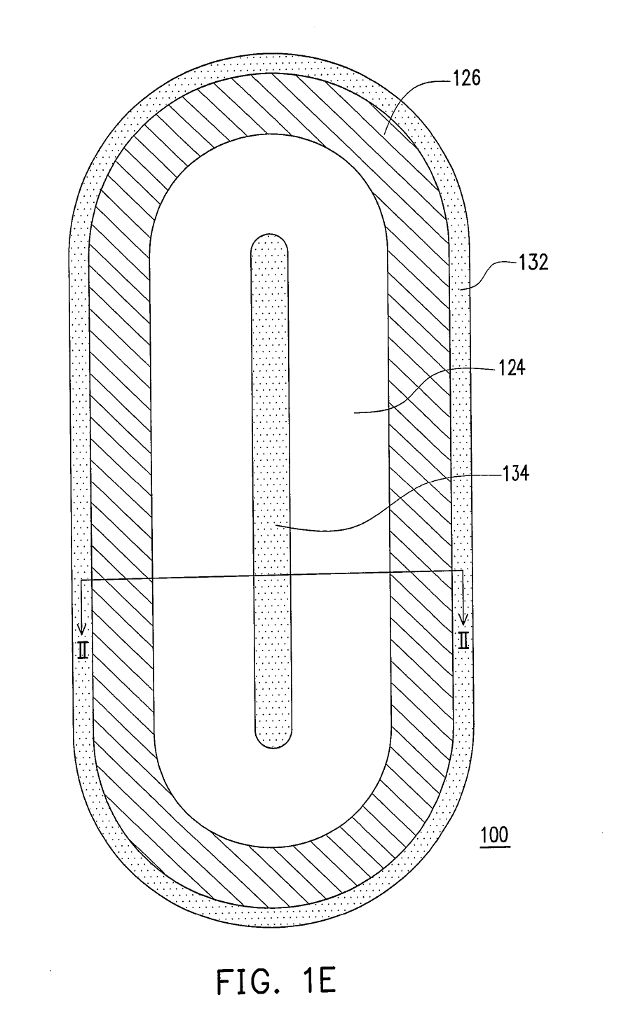

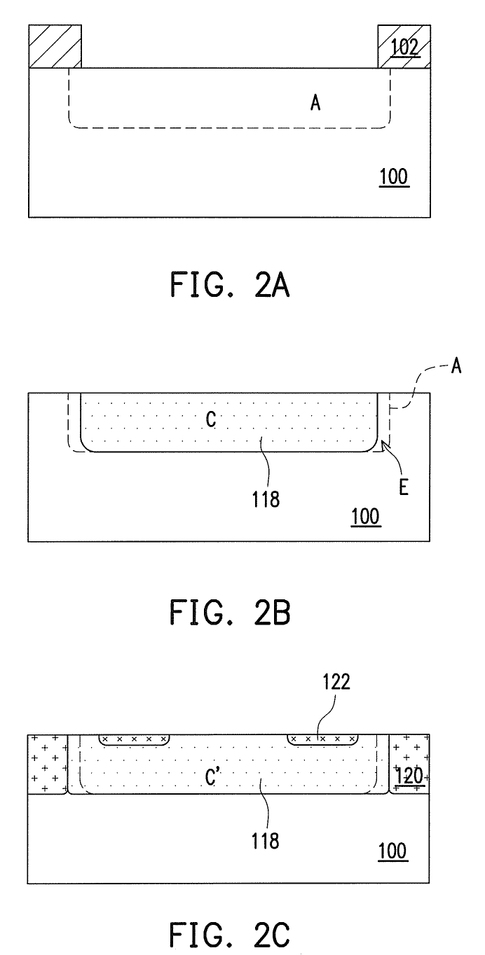

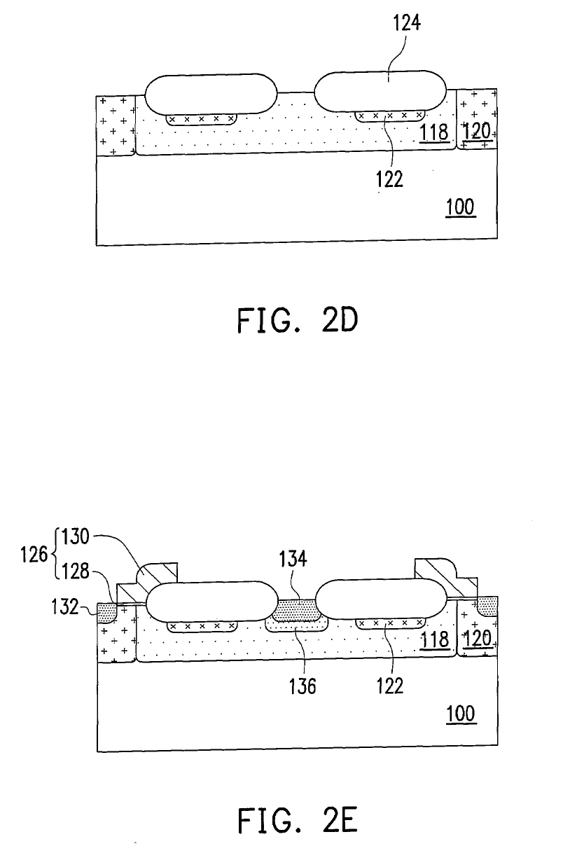

FIGS. 1A to 1E are schematic, top views showing selected process steps of a method for fabricating a high-current, high-voltage metal oxide semiconductor (MOS) device according to an embodiment of the present invention. FIGS. 2A to 2E are cross-section views, along the cutting line II-II in FIGS. 1A to 1E, showing the selected process steps of a method for fabricating a high-current, high-voltage metal oxide semiconductor (MOS) device according to an embodiment of the present invention.

Referring to both FIGS. 1A and 2A, a substrate 100 is provided. The substrate 100 is a semiconductor substrate, such as a silicon substrate or a semiconductor compound substrate, or a silicon-on-insulator substrate. The substrate 100 includes a first conductive type dopants therein. The first conductive type dopants are, for example, P-type or N-type dopants. The P-type dopants include but not limited to boron, while the N-type dopants include phosphorous or arsenic, for example. In this embodiment, P-type dopants are used as the first conductive type dopants for illustration purposes. The substrate 100 also includes a designated deep well region, which further includes an A region and a B region, wherein the A region is a designated scarcely doped region, while the B region is a designated highly doped region. The A region shows, for example, a rectangular shaped, while the B region includes, for example, the two semicircular regions.

Thereafter, a mask layer 102 is formed over the substrate 100. The mask layer 102 is, for example, a photoresist. The mask layer 102 covers the peripheries of the A region and the B region of the deep well region. The mask layer 102 includes a plurality of shielding parts 114 that cover a portion of the scarcely doped A region. The shielding parts 114 may appear rectangular shape (as shown in FIG. 1A), triangular shape (as shown in FIG. 1A-1), arc shape (as shown n FIG. 1A-2) or other shapes. The shielding parts 114 are evenly distributed along the border of the designated scarcely doped A region. The total length ΣL of the border of the designated scarcely doped A region sheltered by the shielding parts 114 is about 1/12 to ⅛ of the length of the border of the designated scarcely doped A region.

In other words, the mask layer 102 includes an opening 104 that exposes a portion of the substrate 100 surface. The opening 104 pattern of the mask layer 102 is enclosed by two sides 106, 108 and two connecting sections 110, 112. Each of the two sides 106, 108 includes a plurality of concavities 116. Each connecting section 110, 112 includes at least one arc. The shapes and sizes of the connecting sections 110, 112 can be the same or different. In this embodiment, the sizes and the shapes of the two connecting sections 110, 112 are the same, and the two connecting sections 110, 112 shows an arch shape, for example, a semicircular shape. The two ends 110a, 110b of the connecting section 110 are respectively connected to one end 106a of the side 106 and one end 108a of the side 108. The two ends 112a, 112b of the connecting section 112 are respectively connected to one end 106b of the side 106 and one end 108b of the side 108. Concavities are formed along the sides 106 and 108 due to the shielding parts 114, which are uniformly distributed along the sides 106 and 108; the sides 106 and 108 thereby show a saw-teeth shape. The sum of the length L1 of the concavities 106 on each side 106, 108 is about 1/12 to ⅛ of the distance L between the two ends 106a and 106b or the distance L between the two ends 108a and 108b. The concavities may be rectangular shape, U-shape, arc shape or other shapes.

Thereafter, referring to FIGS. 1B and 2B, using the mask layer 102 as an implantation mask to perform an ion implantation process, a deep well region 118 having a second conductive type dopants is formed in the substrate 100 exposed by the opening 104. The second conductive type dopants can be N-type dopants or P-type dopants. The P-type dopants include boron, for example, while the N-type dopants include phosphorous or arsenic, for example. When the first conductive type is the N-type, the second conductive type is the P-type. In this embodiment, the first conductive type is the P type while the second conductive type is the N-type for illustration purposes. The implantation power is about 200 KeV to about 400 KeV and the dosage is about 1.0×10¹² to about 9.0×10¹²/cm².

The newly formed N-type deep well region 118 may include a C region and a D region, wherein the C region is configured at the designated scarcely doped A region, while the D region is configured at the designated highly doped B region. The C region and the D region are formed by a single ion implantation process using a single dosage of the dopants. However, due to the sheltering of the shielding parts 114 of the mask layer 102, a plurality of undoped regions E are formed along the border 118a of the C region. In other words, the border 118 of the newly formed C region show a saw-teeth shape, similar to that of the saw-teeth sides 106, 108 of the opening 104. Thereafter, the mask layer 102 is removed, for example, by wet etching methods or dry etching methods.

Referring to both FIGS. 1C and 2C, a p-body region 120 is formed in the substrate 100. The p-body region 120 surrounds the periphery of the N-type deep well region 118. The p-body region is formed by forming a mask layer (not shown) over the substrate 100, following by performing an ion implantation process. The implantation power of this ion implantation process is about 100 KeV to about 250 KeV and the dosage is about 5×10¹² to about 5×10¹³/cm².

Thereafter, a p-top region 122 is formed in the N-type deep well region 118. The p-top region 122 serves to raise the breakdown voltage. The p-top region 122 shows a closed ring shape. The p-top region is formed by forming a mask layer (not shown) over the substrate 100, followed by performing an ion implantation process. The implantation power of this ion implantation process is about 100 KeV to about 250 KeV and the dosage is about 1×10¹² to about 9×10¹²/cm².

Thereafter, a thermal cycle, for example, a thermal annealing process is performed. Since the dopant concentration in the C region is higher, and the dopant concentration in the E region is zero, there is a step-height difference in the dopant concentrations between the two regions. Hence, subsequent to the thermal annealing process, some of the dopants in the C region of the N-type deep well region 118 diffuse to the undoped region E to fill the undoped region E. Ultimately, the area of the C region is expanded to form a rectangular-shaped C′ region and the effective dopant concentration in the C′ region is lowered. The degree of the dopant concentration being lowered is related to the length L1 of the concavities 116 on the saw-teeth sides 106, 108 of the opening 14. The higher of the sum of the length L1 of the concavities 116, the degree of the dopant concentration being lowered increases. In one embodiment, the degree of the dopant concentration being lowered is about 1/12 to ⅛. The D region is configured at two sides of the C′ region, which correspond to the semicircular region B of the opening 104. Subsequent to the thermal annealing process, the outward diffusion of the dopants in the D region is very limited. The degree of reduction of the dopant concentration in the D region is insignificant compared to that in the C′ region. Subsequent to the thermal cycle, the N-type well region that includes the D region with a higher dopant concentration and the C′ region with a lower dopant concentration is formed. In practical application, it is not limited to the thermal cycle be performed after the P-type top region 122 is formed. Rather, the thermal cycle may perform at few process steps after the p-top region 122 is formed or prior to the p-top region 122 is formed. In fact, a thermal cycle of the process may be used to achieve the effect of the thermal cycle.

Experimental results confirm that for a square-shaped device, if the dopant concentration in the N-type deep well region is maintained at the original dose, while the dopant concentration in the p-top region is increased 10% from the original dose, the breakdown voltage of the device may increase from 440 V to 570 V. However, for a circular-shaped device, if the dopant concentration in the N-type deep well region is maintained at original dose, while the dopant concentration in the p-top region is increased 10% from the original dose, the breakdown voltage of the device may decrease from 700 V to 620 V. In other words, for a square-shaped device, the greater the difference in the dopant concentrations between the p-top region and the N-type deep well region, the breakdown voltage is effectively increased. On the other hand, for a circular-shaped device, the greater the difference in the dopant concentrations between the p-top region and the N-type deep well region, the breakdown voltage is decreased due to the characteristics of the device.

Accordingly, if the dopant concentration of the p-top region is maintained at the original dose, and for a circular-shaped well region device, the dopant concentration of the N-type deep well region is maintained the original dose, the breakdown voltage of the device may maintain at about 700 V. However, for a square-shaped well region device, if the dopant concentration of the p-top region is maintained at the original dose, and the breakdown voltage of the device is maintained at 570 V, the dopant concentration of the P-type top region must be reduced to increase the difference in the dopant concentrations between the p-top layer and the N-type deep well region. On the contrary, if the dopant concentration of the p-top region is maintained at a 10% increase of the original dose, and for a square-shaped well region device, if the dopant concentration is maintained at the original dose, the breakdown voltage of the device may maintain at 570 V. However, for a circular-shaped well region device, if the dopant concentration of the p-top region is maintained at a 10% increase of the original dose, and the breakdown voltage is maintained at 700 V, the dopant concentration of the N-well region must increase to reduce the difference in the dopant concentrations between the p-top region and the N-type deep well region.

In the embodiment of this invention, through the design of the pattern of the opening 104 of the mask layer 102, a single ion implantation process is performed for the N-type deep well region to have the C′ region and the D region of different dopant concentrations. In one embodiment, the dopant concentration the C′ region is lowered to 11/12 to ⅞ of that of the D region. Hence, the difference in the dopant concentrations between the C′ region and the p-top region is larger. For the rectangular shape C′ region, a higher breakdown voltage is maintained. The dopant concentration of the D region is higher than that of the C′ region, and the difference in the dopant concentrations between the D region and the p-top region is smaller. For a semicircular-shaped D region, a higher breakdown voltage is maintained.

Thereafter, referring to FIGS. 1D and 2D, an isolation structure 124 showing for example, an enclosed shape, such as ring shape, is formed on the N-type deep well region 118. The isolation structure 124 covers the p-top region 122 and the periphery portion of the N-type deep well region 118, while exposes a portion of the N-type deep well region 118. The isolation structure 124 is, for example, a field oxide layer (FOX) formed by a local thermal oxidation method.

Thereafter, referring to FIGS. 1E and 2E, a gate structure 126 is formed on the substrate 100. The gate structure 126 includes a gate dielectric layer 128 and a gate conductive layer 130. The gate dielectric layer 128 is formed on the surfaces of the p-body region 120 and the N-type deep well region 118. The material of the gate dielectric layer includes but not limited to silicon oxide, silicon nitride, silicon oxynitride or other high dielectric constant (high-k) material. The gate dielectric layer 128 is formed by thermal oxidation or chemical vapor deposition. The gate conductive layer 130 extends from the surfaces of the p-body region 120 and the N-type deep well region 118 to cover a portion of the isolation structure 124. The material of the gate conductive layer includes a silicon-based material, such as doped silicon, undoped silicon, doped polysilicon or undoped polysilicon. When the material of the gate conductive layer 130 is doped silicon or doped polysilicon, N-type dopants or P-type dopants may use. In one embodiment, the gate conductive layer is formed with a doped polysilicon layer and a salicide layer. The material of the salicide layer includes fire-resistant metal such as, nickel, cobalt, titanium, copper, molybdenum, tantalum, tungsten, erbium, zirconium, platinum or alloy thereof.

Thereafter, an N-type source region 132 and an N-type drain region 134 are formed in the substrate 100. The N-type source region 132 shows a closed ring shape and is configured in the p-body region 120, surrounding the periphery of the gate structure 126. The N-type drain region 134, which shows a stripe shape, is formed in the N-type deep well region 118 surrounded by the isolation structure 124. The N-type source region 132 and the N-type drain region 134 are formed by selective ion implantation process. In one embodiment, an N-doped region 136 is formed at the periphery of the N-type drain region 134.

According to the above-mentioned embodiment, through the design of the opening pattern of the mask layer, a singe ion implantation process is required to provide the N-type deep well region with different dopant concentrations in the rectangular region and the semicircular region, respectively. Hence, the high voltage MOS device is provided with a higher current and a higher breakdown voltage.

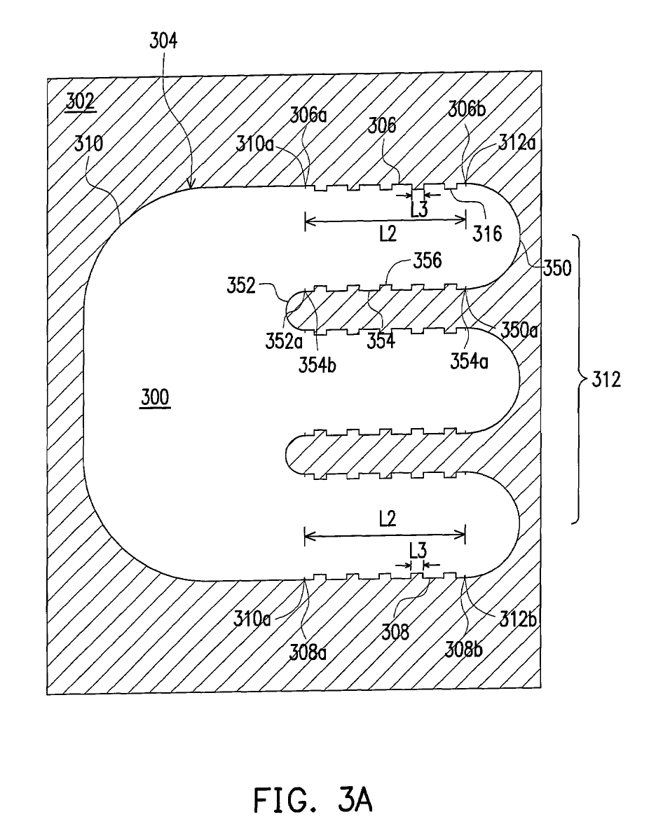

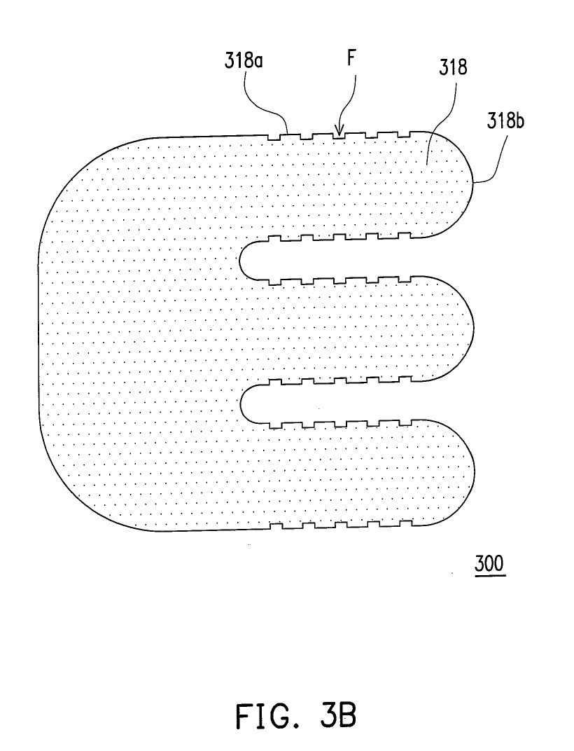

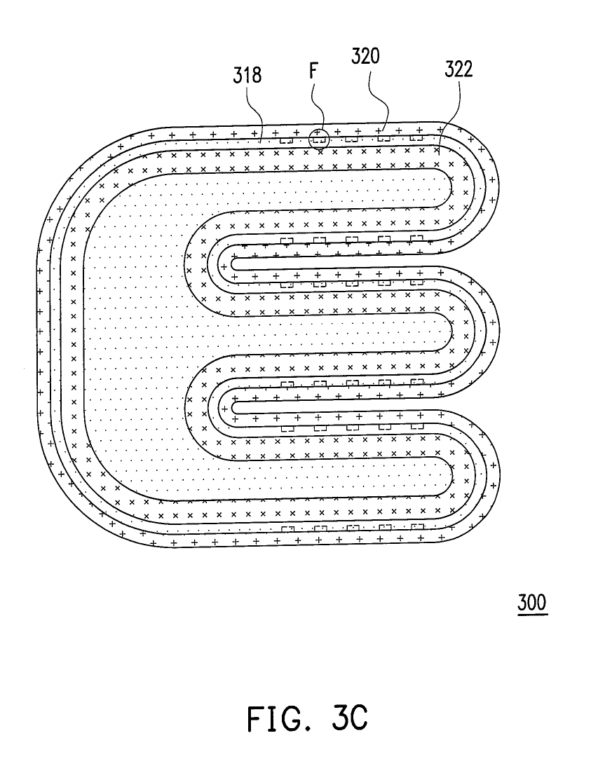

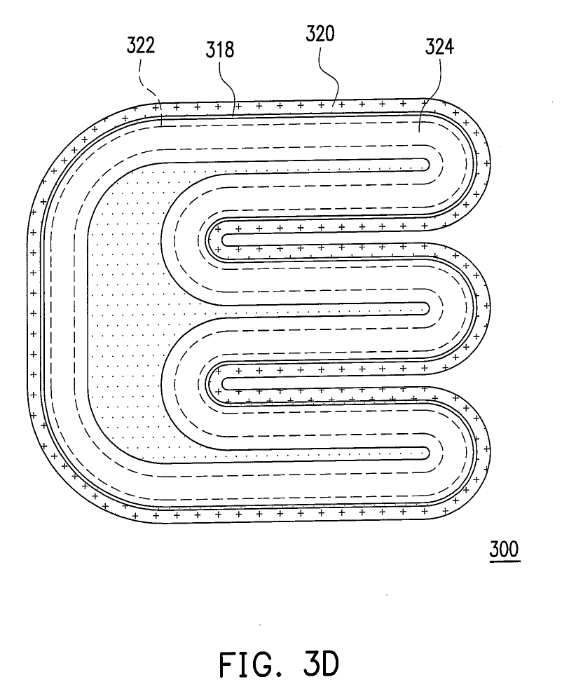

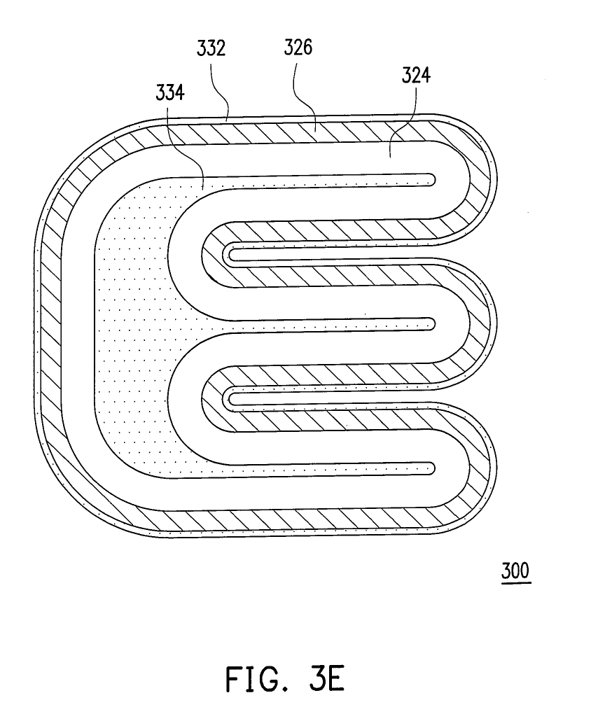

According to the above-mentioned the high voltage MOS device that has a longitudinally extended oval shape, in order to increase the current of the high voltage MOS device, the arrangement of the high voltage MOS device can be altered to other shapes. FIGS. 3A to 3E are schematic, top views showing selected process steps of a method for fabricating a high-current, high-voltage metal oxide semiconductor (MOS) device according to another embodiment of the present invention.

Referring to FIG. 3A, a mask layer 302 is formed over the substrate 300. The mask layer 302 has at least an opening 304 that exposes a portion of the surface of the substrate 300. The substrate 300 is, for example, a semiconductor substrate, such as silicon substrate or a semiconductor compound substrate or a silicon-on-insulator substrate. The substrate 300 includes a first conductive type dopants therein, for example. The first conductive type is, for example, a P-type or an N-type. In this embodiment the first conductive type is a P-type for illustration purposes. The material of the mask layer 302 is, for example, a photoresist material. The opening 304 of the mask layer 302 shows a palm shape.

To be more specific, the opening 304 pattern is enclosed by two exterior sides 306 and 308 and two connecting sections 310, 312. Each exterior side 306, 308 includes a plurality of concavities 316. Each of the connecting sections 310, 312 respectively include at least one arc, and the sizes and the shapes of the connecting sections 310 are substantially different.

In this embodiment, the connecting section 310 is one big arc. The two ends 310a and 310b of the connecting section 310 are respectively connected to one end 306a of the exterior side 306 and one end 308a of the exterior side 308. The two ends 312a and 312b of the connecting section 312 are respectively connected to another end 306b of the exterior side 306 and another end 308b of the exterior side 308. The connecting section 312 includes a plurality of small arcs 350 and a plurality of small arcs 352. The small arcs 350 and the small arcs 352 are arranged alternately in two rows. The connecting section 312 further includes a plurality of interior sides 354, wherein the two ends 354a, 354b of each interior side 354 respectively connect to one end 350a of one of the small arcs 350 and one end 352a of one of the small arcs 352. The interior sides 354 include a plurality of concavities 356. The concavities 316 and 356 are uniformly distributed along the exterior sides 306, 308 and the interior sides 354; hence, the exterior sides 306, 308 and the interior sides 354 show a saw-teeth shape. The sizes and the shapes of the concavities 356 of the interior side 354 and the concavities 316 of the exterior sides 306, 308 may be the same or different. The concavities 356 or 316 can be rectangular shape, U shape, arc shape or other shapes. In FIGS. 3A-3E, the concavities 356 or 316, which are rectangular shape, is used for the illustration of this embodiment of the invention. The sum of the lengths L3 of the concavities of each side 306, 308, 354 is about 1/12 to ⅛ of the distance L2 between the two ends 306a and 306b of the exterior side 306, or the distance L2 between the two ends 208a and 308b of the exterior side 308, or the distance L2 between the two ends 354a and 354b of the interior side 354.

Referring to FIG. 3B, using the mask layer 302 as an implantation mask, an ion implantation process is performed to form a second conductive type doped deep well region 318. In this embodiment, the second conductive type being an N-type is used for illustration purposes. The border 318a of the deep well region, which corresponds to the exterior sides 306, 308 or the interior side 354 of the opening, show a saw-teeth shape and includes a plurality of undoped regions F. The border 318 of the newly formed deep well region 318, which corresponds to the big arc and small arcs 350, 352 appears smooth.

Thereafter, as shown in FIG. 3C, a p-body region 320 is formed in the substrate, the p-body region 320 surrounds the periphery of the deep well region 118. A p-top region 322 is then formed in the N-type deep well region 320, followed by performing a thermal annealing process for the dopants in the deep well region 318 to diffuse to the undoped regions F in order for the dopant concentration in the regions between the saw-teeth border be effectively reduced. The dopant concentration at the smooth border region remains effectively unchanged. Thereafter, referring to FIG. 3D, isolation structures 324 are formed on the N-type deep well region 318, Continuing to FIG. 3E, a gate structure 326, an N-type source region 332 and an N-type drain region 334 are formed on the substrate 300 or on the N-doped region (not shown) formed at the periphery of the N-type drain region 334.

According to the above embodiment, a three-finger palm-shaped opening is used to illustrate the features of the invention. In practical application, a two-finger palm-shaped opening or a multiple-fingers palm-shaped opening or an oval-like shaped opening may used according to the required current.

According to the present invention, through the design of the opening pattern of the mask layer, an N-type deep well region having regions of different dopant concentrations is achieved via a single ion implantation process for the high voltage MOS device to have a high current and a higher breakdown voltage.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of fabricating a deep well region of a high voltage device, the method comprising:
providing a substrate, wherein the substrate comprises a designated deep well region, and the designated deep well region comprises a designated highly doped region and a designed scarcely doped region;
forming a mask layer over the substrate, wherein the mask layer, which covers a periphery of the designated deep well region, comprises a plurality of shielding parts that covers portions of the designated scarcely doped region;
performing an ion implantation process to implant dopants into the designed deep well region by using the mask layer as an implantation mask, wherein a plurality of undoped regions is formed in the designated scarcely doped region covered by the shielding parts; and
inducing the dopants in the designated scarcely doped region to diffuse to the undoped regions so as to form a scarcely doped region in the designated scarcely doped region, and a highly doped region is formed by the designated highly doped region.

2. The method of claim 1, wherein the designated scarcely doped region is rectangular-shaped and the designated highly doped region includes two semicircular regions positioned at two sides of the rectangular-shaped designated scarcely doped region.

3. The method of claim 1, wherein the shielding parts cover a border of the rectangular-shaped designated scarcely doped region.

4. The method of claim 3, wherein the shielding parts are uniformly distributed along the border of the designated scarcely doped region.

5. The method of claim 3, wherein a total length of the border of the designated scarcely doped region covered by the shielding parts is about 1/12 to ⅛ of the length of the border of the designated scarcely doped region.

6. The method of claim 1, wherein the step of inducing the dopants in the designated scarcely doped region to diffuse to the undoped regions comprises performing a thermal cycle.

7. The method of claim 1, wherein the thermal cycle comprises a thermal annealing process.

8. The method of claim 1, wherein a first dosage of the dopants being implanted in the designated highly doped region during the ion implantation process is the same as a second dosage being implanted in the designed scarcely doped region.

9. A method of fabricating a deep well region of a high voltage device, the method comprising:
forming a mask layer over a substrate, wherein the mask layer comprises one opening, and a profile of the opening comprises at least a pattern that is enclosed by two first sides and two connecting sections, wherein the first sides are substantially parallel and are configured with a plurality of first concavities, and two connecting sections, and each connecting section respectively comprises at least an arc and two ends of each connecting section respectively connects to one end of each of the first sides;
performing an ion implantation process to implant dopants in the substrate exposed by the opening by using the mask layer as an implantation mask, wherein a plurality of undoped regions, which corresponds to the first concavities of the opening, is formed in the substrate; and
performing a thermal cycle for the dopants in the substrate to diffuse to the doped regions to form a deep well region.

10. The method of claim 9, wherein sizes and shapes of the two connecting sections are the same.

11. The method of claim 10, wherein each connecting section has an arc shape.

12. The method of claim 11, wherein each connection section is semicircular and the opening has an oval-like shape.

13. The method of claim 9, wherein sizes and shapes of the two connection sections are different.

14. The method of claim 13, wherein one of the two connection sections comprises a large arc, and another one of the two connection sections comprises a plurality of first small arcs and a plurality of second small arcs, and the first small arcs and the second small arcs are alternately arranged in two rows, and the alternately arranged first small arcs and second small arcs are connected by one of second sides that comprises a plurality of second concavities for the opening to show a palm-like shape.

15. The method of claim 14, wherein the second concavities are uniformly distributed along the second sides of the opening.

16. The method of claim 14, wherein a sum of a length of each of the second concavities is about ⅛ to about 1/12 of a distance between two ends of each of the second sides.

17. The method of claim 14, wherein each of the second concavities shows a rectangular shape, a U shape or an arc shape.

18. The method of claim 14, wherein each of the second sides shows a saw-teeth shape.

19. The method of claim 9, wherein the first concavities are uniformly distributed along the first sides of the opening.

20. The method of claim 9, wherein a sum of a length of each of the first concavities is about 1/12 to ⅛ of a distance between two ends of each of the first sides.

21. The method of claim 9, wherein each of the first concavities has a rectangular shape, a U shape or an arc shape.

22. The method of claim 9, wherein each of the first sides has a saw-teeth shape.

23. The method of claim 9, wherein the mask layer comprises a photoresist layer.

24. The method of claim 9, wherein the thermal cycle comprises a thermal annealing process.

25. The method of claim 9, wherein a same dosage of the dopants is implanted in an entire substrate exposed by the opening.
